(19) United States
(12) Patent Application Publication
(10) Pub. No.: US 2025/0393116 A1
(43) Pub. Date: Dec. 25, 2025

(54) ELECTRONIC CONTROL UNIT

(71) Applicant: Robert Bosch GmbH, Stuttgart (DE)

(72) Inventors: Bo Liu, Suzhou (CN); Zhu Li, Suzhou (CN); Xiazhu Yang, Suzhou (CN)

(21) Appl. No.: 19/236,267

(22) Filed: Jun. 12, 2025

(30) Foreign Application Priority Data
Jun. 19, 2024 (CN) 202410796138.0

(51) Int. Cl. H05K 1/02; G01K 1/14; H05K 3/34

(52) U.S. Cl. CPC H05K 1/0203; G01K 1/14; H05K 3/341; H05K 2201/10151; H05K 2201/10318; H05K 2201/10409; H05K 2201/10598

(57) ABSTRACT

An electronic control unit includes a power device, the power device having a first side and a second side opposite to each other. The power device is electrically connected to a circuit board. A temperature sensor is mounted to the circuit board, the temperature sensor and the circuit board are both located on the first side of the power device, and the temperature sensor is in thermal contact with the first side to sense the temperature of the power device. A heat dissipation device is in thermal contact with the second side. The configuration can effectively obtain the temperature of the power device and shorten the heat transfer path.

### BACKGROUND

The present application relates to an electronic control unit.

An electronic control unit (ECU) is a vehicle-mounted control device composed of integrated circuits. The electronic control unit typically has a housing with a circuit board arranged inside. The electronic components on the circuit board, such as a power device, generate heat during operation. The design of the electronic control unit incorporates heat dissipation and insulation for the power device, as well as fixing the power device relative to the housing.

The temperature of the power device is monitored by a dedicated temperature sensor. The temperature sensor is connected to the control unit, which determines whether the operating temperature of the power device is within the safe range, thereby enabling overheat protection for the power device. There are several methods to detect the power device using the temperature sensor, such as monitoring the pin temperature of the power device or sensing the temperature of the heat dissipation device attached to it. When the temperature sensor is mounted on the power device, it must comply with safety regulations. The research by those skilled in the art includes designing the heat transfer path from the power device to the temperature sensor, establishing a temperature prediction model, and determining how to effectively detect the temperature of the power device.

In addition, the existing electronic control unit uses a spring or a pressing component to ensure that the power device is correctly mounted in the housing. The spring or pressing component applies force to press the power device against the housing, securing it in place and eliminating the gap between the power device and the housing, thereby facilitating heat transfer from the power device to the housing.

### SUMMARY

One aspect of the present application is to provide an electronic control unit in which a power device is located and the temperature of the power device is detected.

The electronic control unit comprises a power device, wherein the power device comprises a first side and a second side opposite to each other; a circuit board, wherein the power device is electrically connected to the circuit board; a temperature sensor, wherein the temperature sensor is mounted to the circuit board, the temperature sensor and the circuit board are both located on the first side of the power device, and the temperature sensor is in thermal contact with the first side to sense the temperature of the power device; and a heat dissipation device, wherein the heat dissipation device is in thermal contact with the second side. In one example of the electronic control unit, the power device is soldered to the circuit board via a pin; and/or the temperature sensor is fixed to the circuit board by soldering.

In one example of the electronic control unit, the temperature sensor is bonded to the power device.

In one example of the electronic control unit, the power device has a heat dissipation surface at the second side, and an insulating and heat-conducting structure is located between the heat dissipation surface and the heat dissipation device; and/or the electronic control unit comprises a housing, the circuit board is mounted to the housing, and the heat dissipation device is constructed as a part of the housing.

In one example of the electronic control unit, the insulating and heat-conducting structure is an integrated pad laid on the heat dissipation device or a layer assembly composed of multiple layers.

In one example of the electronic control unit, a flexible film is arranged inside the integrated pad.

In one example of the electronic control unit, the layer assembly comprises a first compensation layer, an intermediate layer and a second compensation layer, the intermediate layer has a composite property of insulation and heat conductivity, the intermediate layer is bonded to the second side through the first compensation layer, and is bonded to the housing through the second compensation layer.

In one example of the electronic control unit, the flexible film is a polyimide film. In one example of the electronic control unit, the intermediate layer is a ceramic substrate.

In one example of the electronic control unit, a force transfer element is arranged around the temperature sensor between the circuit board and the first side, and the force transfer element is constructed to press the power device against the heat dissipation device using the fastening force of the circuit board mounted on the housing.

In one example of the electronic control unit, a thickened platform is provided on the first side to maintain an insulation gap between the chip in the power device and the circuit board.

In one example of the electronic control unit, the thickened platform is provided with a protrusion, the power device has an inspection hole, and the protrusion fits into the inspection hole to secure the thickened platform in place on the first side.

In one example of the electronic control unit, the force transfer element is integrated into the thickened platform, and the force transfer element is bonded to the circuit board.

In one example of the electronic control unit, the circuit board is fastened to the housing by screws.

In one example of the electronic control unit, the electronic control unit comprises multiple groups of power devices, each group of the power devices comprises at least one power device and the temperature of each group of the power devices is sensed by at least one temperature sensor.

In one example of the electronic control unit, there is a gap between the circuit board and the heat dissipation device, and the temperature sensor and the power device are located in the gap.

The temperature sensor contacts the body of the power device and directly senses the temperature of the power device, enhancing the effectiveness of temperature monitoring of the power device. Additionally, the heat transfer path from the power device to the temperature sensor is shortened, enabling swift temperature data retrieval for timely judgment on whether the power device is operating at a safe temperature.

The heat is transferred on one side of the power device to be detected by the temperature sensor, and the heat is transferred on the other side of the power device to dissipate the heat. Heat transfer occurs between the temperature sensor and the power device, and between the heat dissipation device and the power device through contact.

The thermal resistance between the power device at the first side (i.e., the circuit board side) and the circuit board is eliminated by the adhesive, and the thermal resistance between the power device at the second side (i.e., the housing side) and the heat dissipation device is eliminated by the flexible design of the insulating and heat-conducting structure. The temperature sensor is bonded to the power device, which also helps the temperature sensor to obtain an effective temperature signal from the power device.

In addition to insulation and heat transfer, the insulating and heat-conducting structure can also ensure that the power device fits tightly to the heat dissipation device. In the example where the insulating and heat-conducting structure is an integrated pad, a flexible film is provided inside the pad to eliminate the gap between the power device and the heat dissipation device. In the example where the insulating and heat-conducting structure is a layer assembly, compensation layers are provided above and below the intermediate layer to absorb the gap.

By setting a force transfer element between the power device and the circuit board, the power device is pressed against the housing. The force transfer element transfers the fastening force between the circuit board and the housing, and replaces the spring or pressing component as a force applicator of the power device. In addition, the force transfer element, as the main force transmitter, also plays a role in protecting the temperature sensor.

A thickened platform may also be set on the power device to maintain a safe creepage distance between the power device and the circuit board. The thickened platform is conveniently assembled with the power device using the detection hole provided by the power device. In addition, the force transfer element may be integrated with the thickened platform to reduce the number of parts.

In the electronic control unit of the present application, the temperature sensor and the power device share the same circuit board. The power device is arranged in parallel with the circuit board in the gap between the circuit board and the housing. Multiple power devices may be arranged in the gap.

### BRIEF DESCRIPTION OF THE DRAWINGS

Other aspects and features of the present application become apparent through the following detailed description with reference to the accompanying drawings. However, it should be noted that the accompanying drawings are designed for purposes of explanation only and are not intended to limit the scope of the present application, as they should be referenced in conjunction with the appended Claims. It should also be appreciated that the accompanying drawings are merely intended to conceptually illustrate the structures and processes described herein, and unless otherwise noted, are not necessarily drawn to scale.

The present application will be more fully understood by referring to the detailed description of the specific embodiments below in conjunction with the drawings, in which like reference numerals in the drawings always refer to like elements in the view. Among them:

FIG. 1 is a schematic diagram of an example of the electronic control unit of the present application;

FIG. 2 is a schematic diagram of another example of the electronic control unit of the present application;

FIG. 3 is a schematic diagram of another example of the electronic control unit of the present application;

FIG. 4 is a schematic diagram of another example of the electronic control unit of the present application;

FIGS. 5-6 show an example of assembly of the power device in the electronic control unit shown in FIG. 4, wherein FIG. 5 is an assembled power device; FIG. 6 is an exploded view;

FIG. 7 is a schematic diagram of another example of the electronic control unit of the present application.

### DETAILED DESCRIPTION

To help those skilled in the art accurately understand the subject matter claimed in the present application, the specific embodiments of the present application will be described in detail below in conjunction with the accompanying drawings.

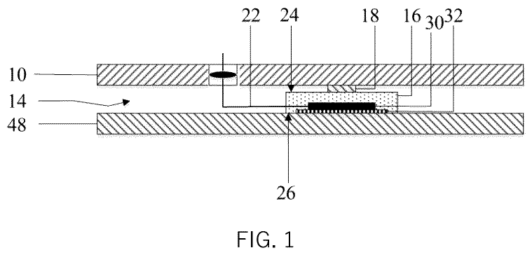

FIG. 1 is a schematic diagram of an example of the electronic control unit of the present application. The electronic control unit is, for example, an inverter. The electronic control unit comprises a circuit board 10 and a heat dissipation device 48. A gap 14 is provided between the circuit board 10 and the heat dissipation device 48. The electronic control unit further comprises a power device 16 and a temperature sensor 18 in the gap 14. The power device 16 is arranged parallel to the circuit board 10 and is electrically connected to the circuit board 10. In one example, a pin 22 of the power device 16 is welded to the circuit board 10 after being bent once. The side of the power device 16 facing the circuit board 10 is a first side 24, and the side facing the heat dissipation device 48 is a second side 26. In one example, the power device 16 is a semiconductor device, comprising a switch element, such as an IGBT (insulated-gate bipolar transistor). The temperature sensor 18 is arranged on the first side 24. The temperature sensor 18 is mounted to the circuit board 10. In one example, the temperature sensor 18 is connected to the circuit board 10 by a through hole technology (THT). In another example, the temperature sensor 18 is connected to the circuit board 10 by a surface mount technology (SMT).

In yet another example, the temperature sensor 18 is an NTC (negative temperature coefficient) sensor (thermistor). The temperature sensor 18 is in thermal contact with the first side 24 of the power device 16, and the heat dissipation device 48 is in thermal contact with the second side 26 of the power device 16. The power device 16 has a heat dissipation surface at its second side 26. The power device 16 is provided in its interior near the second side 26 with a heat sink 32 for dissipating heat for a chip 30. The heat sink 32 is arranged close to the chip 30. The temperature sensor 18 is arranged on a side away from the heat sink 32. In the illustrated example, the chip 30 is arranged below the interior of the power device 16, the heat sink 32 is arranged on the second side 26, and the temperature sensor 18 is arranged on the first side 24.

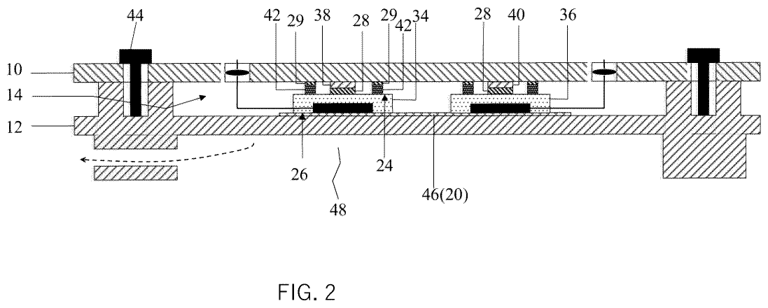

FIG. 2 is a schematic diagram of another example of the electronic control unit of the present application. The electronic control unit comprises a circuit board 10 and a housing 12, and the circuit board 10 is mounted to the housing 12. A gap 14 is provided between the circuit board 10 and the housing 12. Two power devices are provided in the gap 14. In other examples, the number of power devices may be greater. The first power device 34 and the second power device 36 are arranged in the same manner above the first side 24 thereof. Each power device is sensed by a corresponding temperature sensor. The first power device 34, the second power device 36, the first temperature sensor 38, and the second temperature sensor 40 are all connected to the circuit board 10. An adhesive 28 is filled between the first temperature sensor 38 and the first side 24 of the first power device 34. An adhesive 28 is also filled between the second temperature sensor 40 and the first side 24 of the second power device 36. The adhesive 28 may eliminate the gap between the first and second temperature sensors 38, 40 and the first side 24, so that the first and second temperature sensors 38, 40 are respectively in thermal contact with the bodies of the first and second power devices 34, 36 via the adhesive 28, thereby obtaining the temperatures of the first and second power devices 34, 36. The adhesive 28 has a certain thermal conductivity. The thermal resistance of the adhesive 28 will be included in the temperature prediction model of the first and second power devices 34, 36. The heat transfer path from the bodies of the first and second power devices 34, 36 to the first and second temperature sensors 38, 40 is shortened, and the temperature data may be quickly obtained by the control unit, which is conducive to the timely judgment of the control unit. In one example, the adhesive 28 is a glue with a certain thermal conductivity, which is applied to the surface of an object and solidified. An insulating and heat-conducting structure 20 is disposed between the second sides 26 of the first and second power devices 34, 36 and the housing 12, which is responsible for electrically insulating the first and second power devices 34, 36 from the housing 12 and transferring heat from the first and second power devices 34, 36.

In addition, a force transfer element 42 is arranged around the first temperature sensor 38. As shown in the example in the figure, the force transfer elements 42 are arranged on both sides of the first temperature sensor 38. The force transfer elements 42 are responsible for pressing the first power device 34 against the housing 12 using the fastening force of the circuit board 10 mounted to the housing 12. The fastening force is generated by the circuit board 10 being screwed into the housing 12 by screws 44. The force transfer element 42 may be made of plastic. In order to eliminate the gaps that may exist between the force transfer elements 42 and the circuit board 10 (for example, these gaps are caused by assembly errors), adhesive 29 is filled between the force transfer elements 42 and the circuit board 10 on both sides. The adhesive 29 may be the same as the adhesive 28 near the temperature sensors 38, 40. The fastening force of the circuit board 10 to the housing 12 is transmitted to the power devices 34, 36 via the force transfer elements 42, without passing through the temperature sensor, thereby protecting the temperature sensor. The arrangement of the second power device 36 and the second temperature sensor 40 is the same as that of the first power device 34 and the first temperature sensor 38, and will not be described in detail herein.

The insulating and heat-conducting structure 20 is an integrated pad 46 laid between the second side 26 and the housing 12. The pad 46 has insulating and heat-conducting properties, and a flexible film is arranged inside the pad 46 to eliminate the gaps that may exist between the first and second power devices 34, 36 and the housing 12 during assembly. When multiple power devices are arranged in the electronic control unit, they are prone to deviation during assembly, and the flexible film may absorb the error, so that the stress distribution between the multiple power devices is uniform. In one example, the flexible film is a polyimide film (PI film). The pad is extremely thin, measuring just 0.5 mm, by laying and assembling, making it suitable for situations where the gap between the circuit board and the housing is restricted.

The heat dissipation device 48 is disposed adjacent to the insulating and heat-conducting structure 20 and is constructed as a part of the housing 12.

A cooling liquid may flow through the heat dissipation device 48. In the illustrated example, the heat dissipation device 48 is disposed below the integrated pad 46, and the heat of the first and second power devices 34, 36 is transferred downward to the housing 12 via the integrated pad 46 and is then carried away by the heat dissipation device 48, as indicated by the dashed arrows.

The assembly process is as follows.

First, a circuit board assembly is formed, including the two temperature sensors 38, 40 soldered to the circuit board 10 respectively, the adhesive 28 applied on the surface of the temperature sensors 38, 40 or the adhesive 28 applied to the surface of two power devices 34, 36, at which time the pins of the power devices 34, 36 have been bent; the pins of the power devices 34, 36 inserted into the soldering holes of the circuit board 10 for positioning, and the temperature sensors 38, 40 combined with the corresponding power devices 34, 36 via the adhesive 28, or the power devices 34, 36 combined with the corresponding temperature sensors 38, 40 via the adhesive 28. After the temperature sensors 38, 40 and the power devices 34, 36 are combined together, the pins are soldered.

Then the circuit board assembly is fixed, including an integrated pad 46 laid on the housing 12, the circuit board assembly placed on the integrated pad 46, the fastening holes of the circuit board 10 aligned with the threaded holes of the housing 12, the screws 44 screwed in, and the circuit board assembly fastened while the two power devices 34, 36 are pressed against the housing 12.

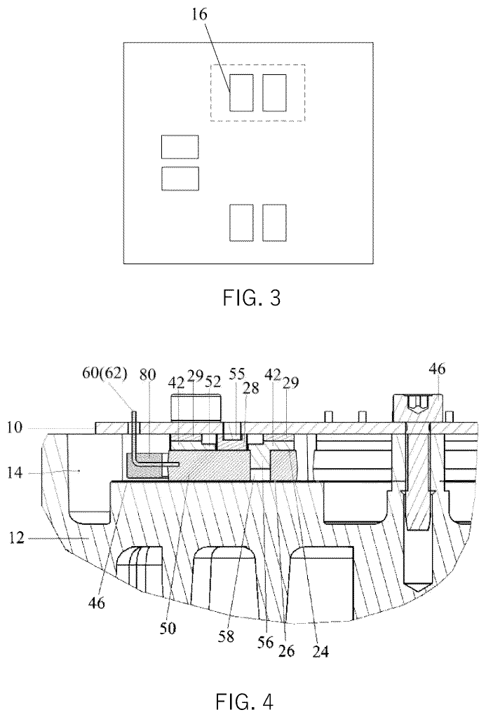

FIG. 3 is a schematic diagram of another example of the electronic control unit of the present application in a top view. The electronic control unit comprises six power devices 16, wherein two power devices form a group. Therefore, there are three groups of power devices in total, and they are arranged separately. Taking a group of power devices as a unit, as shown in the dotted box in the figure, the arrangement of the power devices in the block diagram may be the same as that of the example shown in FIG. 2, and the number of temperature sensors may also be slightly changed, so that each power device is no longer equipped with a temperature sensor. That is, in a group of power devices, two power devices work together, so they are in similar working conditions. In this case, the second temperature sensor may be omitted, and only the temperature of the first power device is sensed by the first temperature sensor.

FIG. 4 is a schematic diagram of another example of the electronic control unit of the present application. The same contents as those in the example shown in FIG. 4 and FIG. 2 are not repeated here. The difference is that a thickened platform 52 is arranged above the first side 24 of the third power device 50, the force transfer elements 42 on both sides are integrated via the thickened platform 52, and a hole 54 (see FIG. 6) is provided at a position corresponding to the third temperature sensor 55 in the middle to leave space for the adhesive 28 and the third temperature sensor 55. The thickened platform 52 is made of plastic. The thickened platform 52 may ensure that there is a sufficient insulation distance between the chip in the third power device 50 and the circuit board 10. The thickened platform 52 may also reasonably distribute the fastening force from the force transfer element 42 to the surface of the first side 24 of the third power device 50, so that the third power device 50 is reliably pressed against the housing 12.

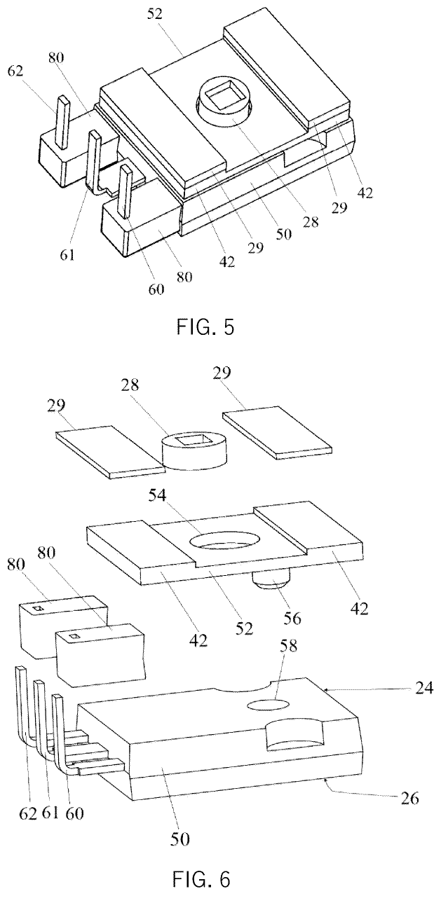

FIGS. 5-6 are schematic diagrams of an example of assembling the thickened platform and the third power device. The thickened platform 52 is provided with a protrusion 56 on the side away from the force transfer element 42, and the protrusion 56 may be filled into the inspection hole 58 of the third power device 50, so as to position the thickened platform 52 relative to the third power device 50.

The third power device 50 has multiple pins in the lateral direction. By selectively performing a potting process on some of the pins, the insulation distance between the pins may be ensured without modifying the pin spacing. In the example in the figure, the third power device 50 has three pins 60, 61, 62. Potting 80 is performed on the two outermost pins 60, 62, and no treatment is performed on the middle pin 61, so as to improve the insulation.

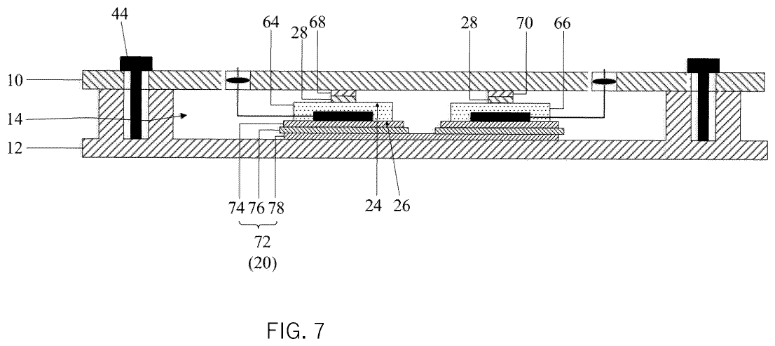

FIG. 7 is a schematic diagram of another example of the electronic control unit of the present application. The electronic control unit comprises two power devices in the gap 14 between the circuit board 10 and the housing 12. The fourth power device 64 and the fifth power device 66 are arranged in the same manner above the first side 24 thereof. Each power device is sensed by a corresponding temperature sensor. The fourth power device 64, the fifth power device 66, the fourth temperature sensor 68, and the fifth temperature sensor 70 are all connected to the circuit board 10. The adhesive 28 is filled between the fourth temperature sensor 68 and the first side 24 of the fourth power device 64. The adhesive 28 is also filled between the fifth temperature sensor 70 and the first side 24 of the fifth power device 66.

An insulating and heat-conducting structure is arranged on the second side 26 of the fourth power device 64 and the fifth power device 66. The insulating and heat-conducting structure 20 is a layer assembly 72 composed of multiple layers. The layer assembly 72 comprises a first compensation layer 74, an intermediate layer 76, and a second compensation layer 78. The intermediate layer 76 has a composite property of insulation and heat conductivity. In one example, the intermediate layer 76 is a ceramic substrate, which has insulation and high heat conductivity. The first compensation layer 74 is arranged between the second side 26 of the fourth and fifth power devices 64, 66 and the intermediate layer 76. The second compensation layer 78 is arranged between the intermediate layer 76 and the housing 12. Corresponding to the two power devices 64, 66, the number of the first compensation layer 74 and the intermediate layer 76 is the same as that of the power devices, and the second compensation layer 78 may be integrated into one part. The compensation layers are arranged on both the upper and lower sides of the intermediate layer 76, which is conducive to helping absorb assembly errors generated on the upper and lower sides of the intermediate layer 76 during the assembly process, such as generated during the assembly process or generated by the roughness of the intermediate layer 76. The first compensation layer 74 and the second compensation layer 78 both have heat conductivity to help heat transfer from the fourth and fifth power devices 64, 66 to the intermediate layer 76 and then to the housing 12. The first compensation layer 74 and the second compensation layer 78 also eliminate the gap between the intermediate layer 76 and the fourth and fifth power devices 64, 66 and the gap between the intermediate layer 76 and the housing 12, reducing air thermal resistance. In one example, the first compensation layer 74 and the second compensation layer 78 are glues with a certain thermal conductivity. They are formed on the surface between the corresponding objects to be combined through an application step, and the corresponding objects are combined after curing. In one example, the first compensation layer 74 and the second compensation layer 78 are made of the same glue as the adhesive 28. In other examples, the first compensation layer 74 and the second compensation layer 78 are made of other adhesives different from the adhesive 28. The first compensation layer 74 and the second compensation layer 78 may use the same glue or different glues.

The assembly process is as follows.

The intermediate layer 76 is combined with the power device 64 or 66. The two power devices 64, 66 are combined with their corresponding intermediate layers 76 by applying the first compensation layer 74. The pins of the power devices 64, 66 may be bent first.

The second compensation layer 78 is applied on the housing 12, and two power devices 64, 66 combined with respective intermediate layers 76 are assembled on the second compensation layer 78, and then the temperature sensors 68, 70 are combined, including the two temperature sensors 68, 70 welded to the circuit board 10 respectively, the adhesive 28 applied on the surface of the temperature sensors 68, 70 or the adhesive 28 applied to the surfaces of the two power devices 64, 66; the pins of the power devices 64, 66 inserted into the welding holes of the circuit board 10 for positioning, and the temperature sensors 68, 70 are combined with the corresponding power devices 64, 66 via the adhesive 28, or the power devices 64, 66 are combined with the corresponding temperature sensors 68, 70 via the adhesive 28. After the temperature sensors 68, 70 and the power devices 64, 66 are combined together, the screws 44 are screwed in to fix them, and then the pins are welded to complete the final assembly.

In the example shown in FIG. 7, the force transfer element is eliminated. Instead, the heat of the power devices 64, 66 is successfully transferred to the housing 12 by the reliable combination of the intermediate layer 76 and the power devices 64, 66 and the reliable combination of the intermediate layer 76 and the housing 12. In the assembly process, the intermediate layer 76 is first combined with the power devices 64, 66 through the first compensation layer 74, and then combined with the housing 12 through the second compensation layer 78, and then the power devices 64, 66 are combined with the temperature sensors 68, 70, and then the power devices 64, 66 are fixed and welded to the circuit board 10 by screws 44. In an alternative example, the force transfer element 42 may be arranged. In this alternative example, the assembly process includes the power devices 64, 66 combined with the temperature sensors 68, 70 first, and then welded with the circuit board 10 to form a circuit board assembly, and the intermediate layer 76 is combined between the power devices 64, 66 and the housing 12, and the circuit board assembly is reliably combined with the intermediate layer 76 and the housing 12 by screwing in the screws 44.

While specific examples of the present application have been shown and described in detail to illustrate the principles of the present application, it will be appreciated that the present application may be implemented in other ways without departing from such principles.

1. An electronic control unit comprising:
a power device (16), the power device (16) comprising a first side (24) and a second side (26) opposite to each other,
a circuit board (10), the power device (16) being electrically connected to the circuit board (10),
a temperature sensor (18), the temperature sensor (18) being mounted to the circuit board (10), the temperature sensor (18) and the circuit board (10) both being located on the first side (24) of the power device (16), the temperature sensor (18) being in thermal contact with the first side (24) to sense a temperature of the power device (16), and
a heat dissipation device (48), the heat dissipation device (48) being in thermal contact with the second side (26).

2. The electronic control unit according to claim 1, wherein the power device (16) is soldered to the circuit board (10) through pins; and/or
the temperature sensor (18) is fixed to the circuit board (10) by soldering.

3. The electronic control unit according to claim 1, wherein the temperature sensor (18) is bonded to the power device (16).

4. The electronic control unit according to claim 1, wherein the power device (16) has a heat dissipation surface at the second side (26), and an insulating and heat-conducting structure (20) is located between the heat dissipation surface and the heat dissipation device (48); and/or
the electronic control unit comprises a housing (12), the circuit board (10) is mounted to the housing (12), and the heat dissipation device (48) is constructed as a part of the housing (12).

5. The electronic control unit according to claim 4, wherein the insulating and heat-conducting structure (20) is an integrated pad (46) laid on the heat dissipation device (48) or a layer assembly (72) composed of multiple layers.

6. The electronic control unit according to claim 5, wherein
a flexible film is arranged inside the integrated pad (46); or
the layer assembly (72) comprises a first compensation layer (74), an intermediate layer (76) and a second compensation layer (78), wherein the intermediate layer (76) has a composite property of insulation and heat conduction, and the intermediate layer (76) is combined with the second side (26) through the first compensation layer (74), and is combined with the heat dissipation device (48) through the second compensation layer (76).

7. The electronic control unit according to claim 6, wherein the flexible film is a polyimide film; the intermediate layer (76) is a ceramic substrate.

8. The electronic control unit according to claim 4, wherein a force transfer element (42) is arranged around the temperature sensor between the circuit board (10) and the first side (24), and the force transfer element (42) is configured to press the power device against the heat dissipation device (48) using a fastening force of the circuit board (10) mounted on the housing (12).

9. The electronic control unit according to claim 8, wherein the first side (24) is provided with a thickened platform (52) to ensure an insulation gap between a chip (30) in the power device and the circuit board (10);
the thickened platform (52) is provided with a protrusion (56), wherein the power device has an inspection hole (58), and the protrusion (56) is filled into the inspection hole (58) to secure the thickened platform (52) in place on the first side (24).

10. The electronic control unit according to claim 9, wherein the force transfer element (42) is integrated into the thickened platform (52), and the force transfer element (42) is bonded to the circuit board (10).
